(19) United States
(12) Patent Application Publication
(10) Pub. No.: US 2006/0113281 A1
(43) Pub. Date: Jun. 1, 2006

(54) Method of precise wafer etching

(76) Inventor: Kuo-Lung Sung, Pan Chiao City (TW)

Correspondence Address: LEONG C LEI, PMB # 1008, 1867 YGNACIO VALLEY ROAD, WALNUT CREEK, CA, 94598, US

(21) Appl. No.: 10/996,421

(22) Filed: Nov. 26, 2004

(51) Int. Cl. C03C 25/68; H01L 21/461; C23F 1/00

(52) U.S. Cl. 216/58; 438/706

(57) ABSTRACT

A method of precise wafer etching includes the provision of a nozzle for spraying an etchant onto a crystal plate which is disposed opposite to the nozzle and can be born by a rotating device, such that the crystal plate to be etched will take the nozzle as the center for revolution, and during the revolution, rotate on its own axis, thus the etchant can be flushed and evenly distributed on the surface of the crystal plate. Accordingly, the surface of the crystal plate can be etched much more precisely.

### BACKGROUND OF THE INVENTION

(a) Technical Field of the Invention

The present invention relates to a method of precise wafer etching, particularly to a method where when a crystal plate to be processed is being etched (by dry etching or wet etching), the size of the reacted material on the surface of the processed crystal plate can be controlled much more precisely.

(b) Description of the Prior Art

The present invention relates to a method of precise wafer etching, particularly to a method where when a crystal plate to be processed is being etched (by dry etching or wet etching), the size of the reacted material on the surface of the processed crystal plate can be controlled much more precisely.

### SUMMARY OF THE INVENTION

The primary purpose of the present invention is to provide a method of precise wafer etching, which can permit a crystal plate be etched with a precise depth and shape, thus reducing defect rate.

The second object of the invention is to provide a method of precise wafer etching, which can allow the etching solution evenly distributed, thereby speeding the manufacture and reducing the costs.

To obtain the above objects, the method of precise wafer etching according to the invention has the crystal plate and the processing nozzle disposed opposite to each other, such that the nozzle can spray an etching substance onto the crystal plate opposite thereto. The crystal plate will take the nozzle as the center for revolution, and during the revolution, rotate on its own axis, such that the etchant can flush the surface of the crystal plate and evenly distribute.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of a conventional dry etching process.

FIG. 2 shows the forming after the conventional dry etching process.

FIG. 3 is a perspective view of a conventional wet etching process.

FIG. 4 shows the forming after the conventional wet etching process.

FIG. 5 is a perspective view of a conventional infiltrative etching process.

FIG. 6 shows the forming after the conventional infiltrative etching process.

FIG. 7 is a perspective view of the rotating device according to the present invention.

FIG. 8 is an exploded view of the rotating device according to the invention.

FIG. 9 is a top view of the rotating device according to the invention.

FIG. 10 shows the wet etching process according to the invention.

FIG. 11 shows the forming after the wet etching process according to the invention.

FIG. 12 is a perspective view of the etching device according to the invention.

FIG. 13 is a perspective view of the rotating device according to another embodiment of the invention.

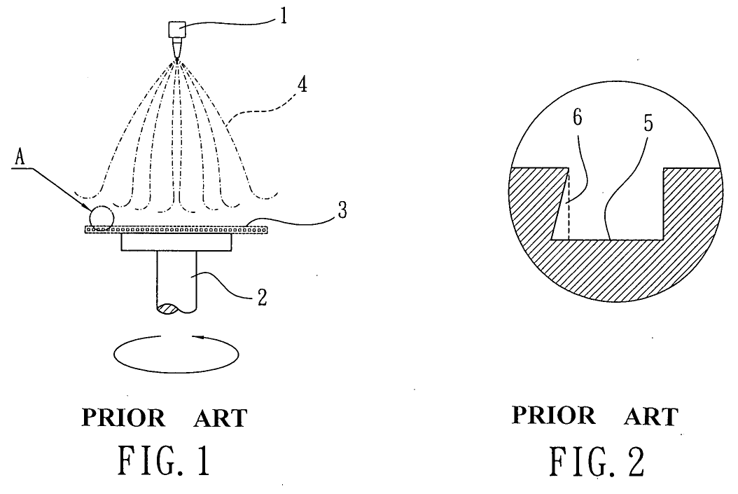

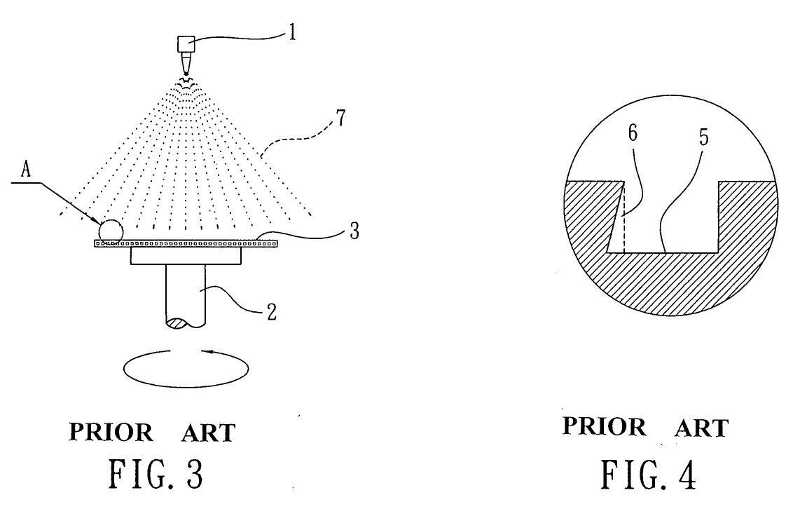

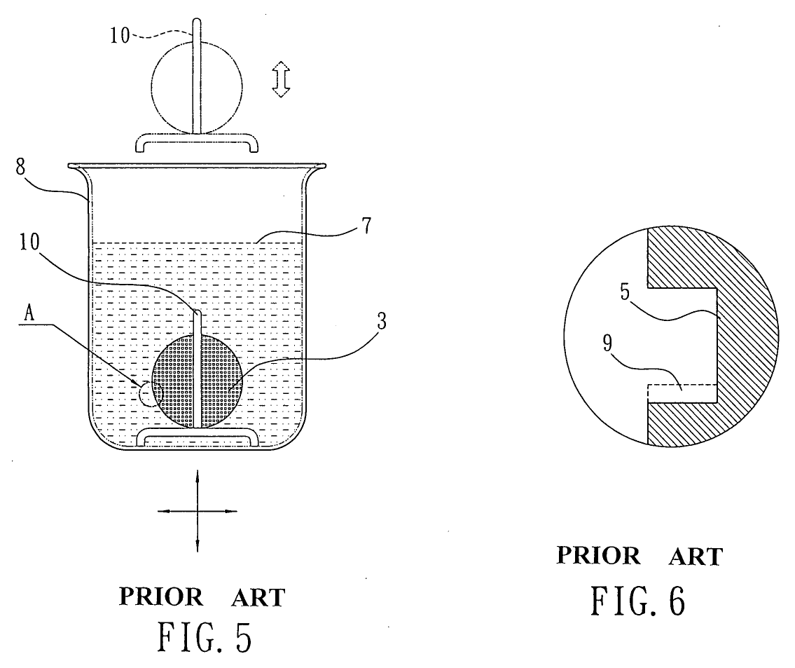

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

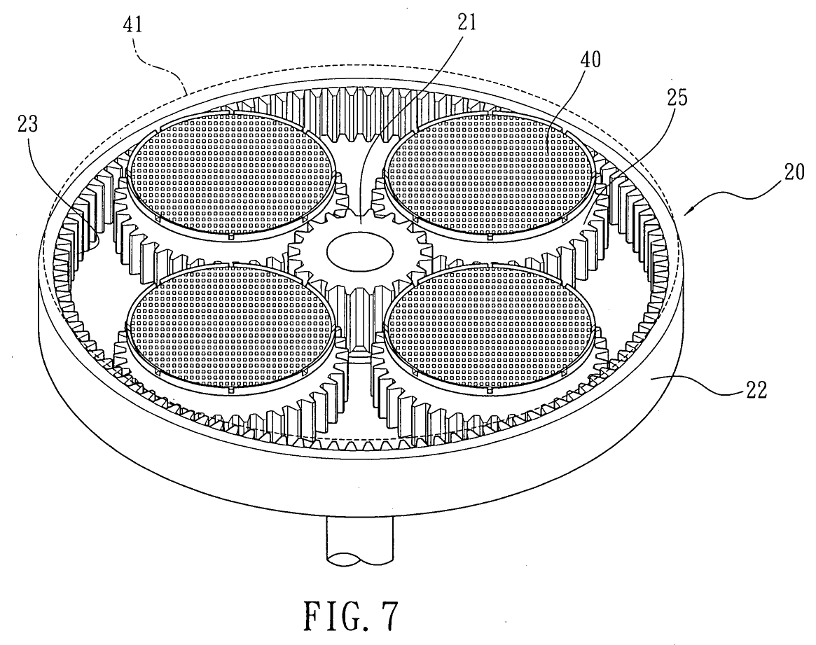

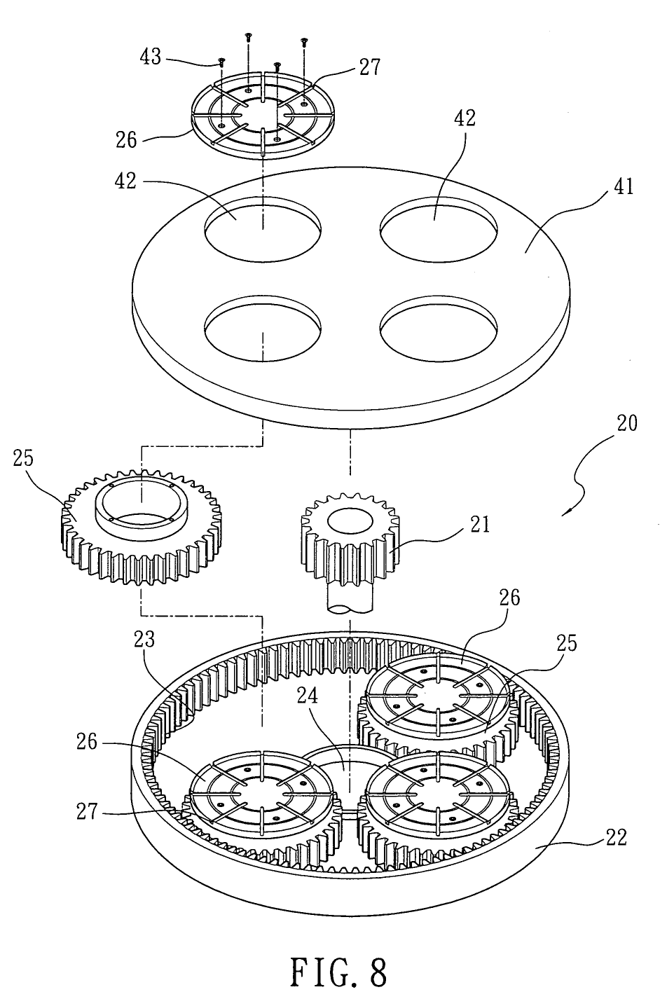

As shown in FIGS. 7 and 8, an embodiment of the invention is designed with a rotating device 20, which is composed of a driving wheel 21, a loop 22 that is provided with interior gears 23 on the inner wall, a hole 24 at the center, and at least one gear 25 against the interior wall. The driving wheel 21 goes through the hole 24, the at least one gear 25 is engaged between the driving wheel 21 and the interior gears 23, a loading disk 26 can be fastened above each gear 25, and the periphery of the loading disks 26 is provided with gaps 27 for clamping crystal plates.

In a preferred embodiment of the invention, a cover 41, which is provided with pluralities of holes 42, can mounted on the gears 25, such that the gears 25 can extrude from the holes 42 for locking with the loading disks 26 via screws 43.

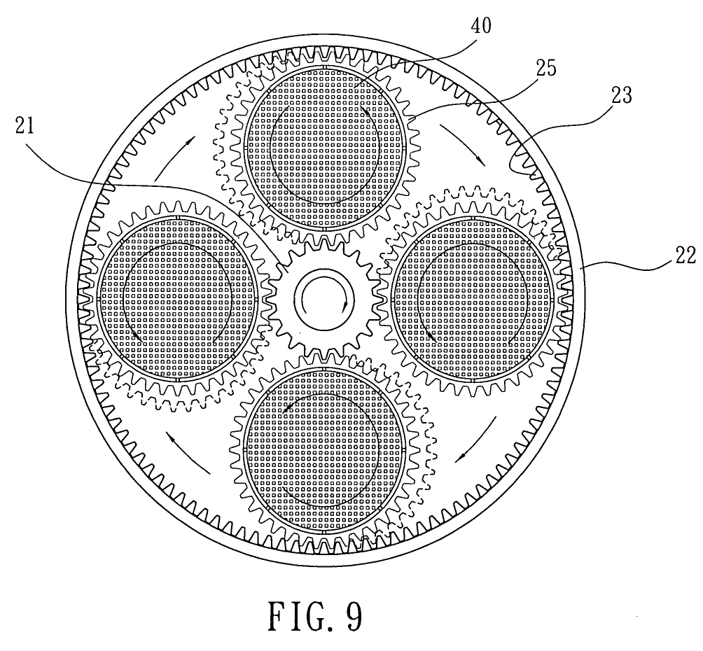

As shown in FIG. 9, after completion of the above-mentioned rotating device 20, the driving wheel 21 will be actuated by a motor. While the loop 22 is designed as a still element, the loading disks 26 will rotate on their own axis due to the engagement of each gear 25 and interior gears 23, thus the gears 25 will generate a revolution subject to the center of the driving wheel 21. As the gears 25 are engaged between the driving wheel 21 and the interior gears 23, the loading disks 26 can rotate on their own axis and concomitantly go along the revolution. Accordingly, any crystal plate 40 disposed on the loading disks 26 may likewise rotate on their own axis and go along the revolution.

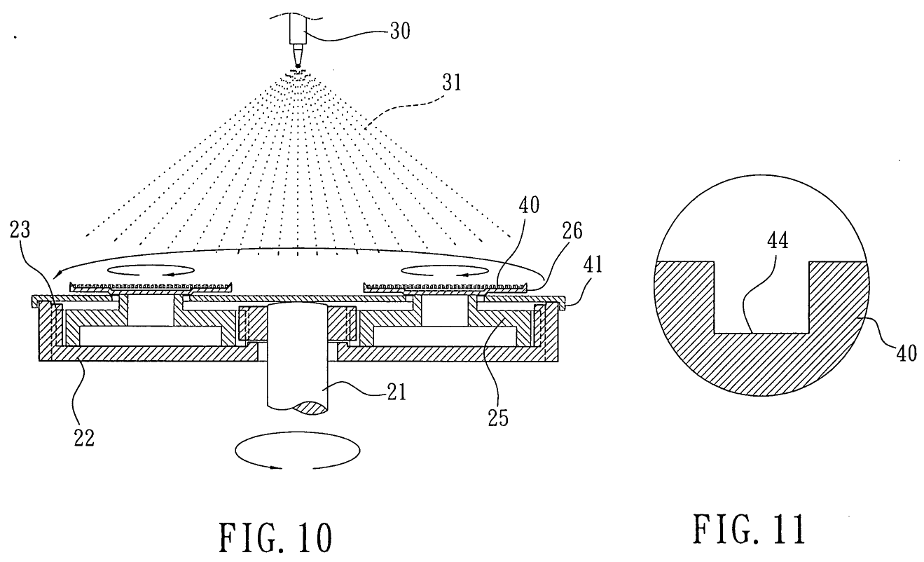

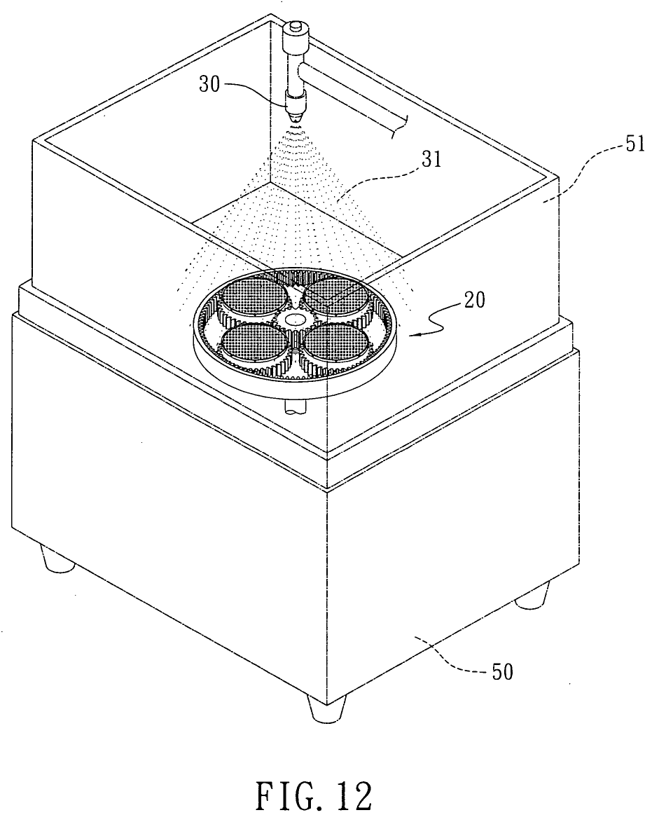

As shown in FIGS. 10 and 12, the rotating device 20 according to the invention can be disposed on a machine, which is provided with closable protective covering 51. A nozzle 30 is provided above the protective covering 51 for spraying etchant. As the preferred embodiment as shown refers to a wet etching, the etchant is in form of an etching solution 31. In the case of dry etching, the etchant would be in form of an etching gas. The nozzle 30 is installed right above the circle center of the driving wheel 21 to serve as the working origin. Besides, each crystal plate 40 is disposed on each of the loading disks 26. After the motor output axle (not shown) has driven the driving wheel 21 to rotate, thereby driving the gears 25 engaged with the interior gears 23 to move. In the preferred embodiment shown, the number of the gears 25 inside the loop 22 is set as 4. Being driven by the driving wheel 21, the gears 25 will take the nozzle 30 as the center to make revolution, and concomitantly rotate on their own axles due to the engagement thereof. Accordingly, when the etching solution 31 is dispersed from up to down, it will distribute evenly all round to form a coating on the processed surface of the crystal plate 40, thus obtain a precise control on the etching depth.

As shown in FIG. 11, since the etching solution is evenly distributed, the depth and shape of the processed groove 41 on the crystal plate 40 are under precise control.

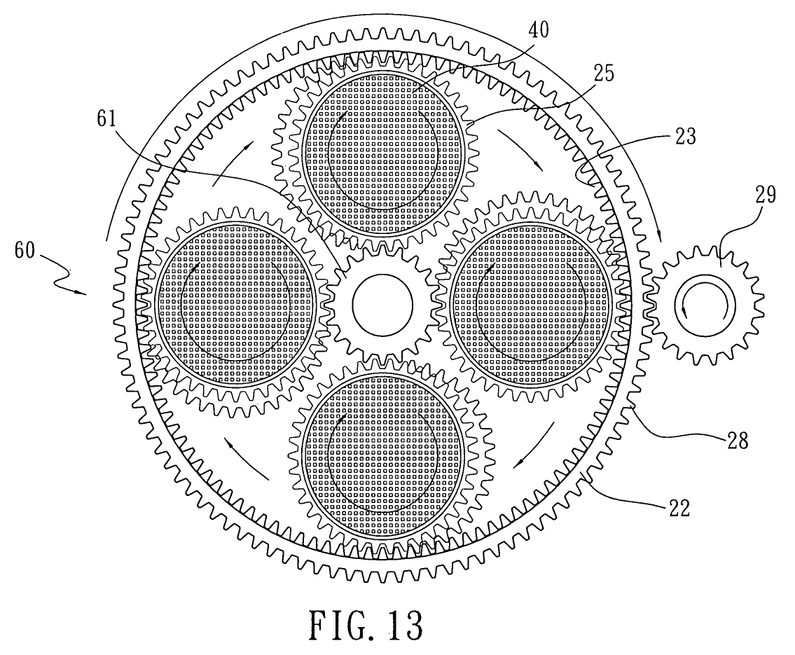

FIG. 13 shows a rotating device 60 of a further embodiment of the invention. In order to make the crystal plates 40 disposed on the loading disks 26 to take the nozzle 30 as the center to make revolution, a central wheel 61 can be provided at the center of the rotating device 60. While the central wheel 61 is set still, the connection between the loop 22 and gears 25 remain unchanged. Besides, exterior gears 28 are provided at the periphery of the loop 22 for engaging with a driving wheel 29. When the driving wheel 29 is driven by a motor to rotate, all the loading disks 26 will, in addition to revolution, rotate on their own axis like planets.

Concluded above, when applying the invention to process a crystal plate, the etching depth and size can be precisely controlled, thereby enhancing the process efficiency and product quality. In comparison with the technology in the prior arts, the integral value has been greatly increased.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A method of precise wafer etching, including provision of a nozzle for spraying an etchant, a crystal plate to be etched being disposed opposite to the nozzle, characterized in that:
the crystal plate to be etched will take the nozzle as the center for revolution, and during the revolution, rotate on its own axis, such that the etchant can be flushed and evenly distributed on the surface of the crystal plate.

2. The method of precise wafer etching according to claim 1, wherein the nozzle is disposed at an upper position.

3. The method of precise wafer etching according to claim 1, wherein the crystal plate is disposed at a lower position.

4. The method of precise wafer etching according to claim 1, wherein the etchant sprayed from the nozzle is an etching solution.

5. The method of precise wafer etching according to claim 1, wherein the etchant sprayed from the nozzle is an etching gas.
